(19) United States
(12) Patent Application Publication
(10) Pub. No.: US 2024/0410930 A1
(43) Pub. Date: Dec. 12, 2024

(54) A METHOD OF DETECTING A PARTIAL DISCHARGE SIGNAL

(71) Applicant: MODEMTEC S.R.O., Trinec (CZ)

(72) Inventors: Jindrich LIŠKA, Starý Plzenec (CZ); Jan JAKL, Plzen, Bolevec (CZ); Sven KÜNKEL, Plzen, Jižní Predmestí (CZ)

(73) Assignee: MODEMTEC S.R.O., Trinec (CZ)

(21) Appl. No.: 18/699,074

(22) PCT Filed: Sep. 23, 2022
(86) PCT No.: PCT/CZ2022/000039

§ 371 Date: Apr. 5, 2024

(30) Foreign Application Priority Data
Oct. 7, 2021 (CZ) PV 2021-468

(51) Int. Cl. G01R 31/12

(52) U.S. Cl. CPC G01R 31/1272

(57) ABSTRACT

A method of detecting a partial discharge signal from a measured signal by a measuring device at at least one point of an electrical network. The method includes first initializing the variables in the detection device, and loading the parameters Nvar, lag_max, dead_max, then the measured wide-spectrum is loaded at then least once an analog signal that is converted into a digital signal in a digitising means, which is further band-pass filtered so that components unrelated to a manifestation of a partial discharge are removed, with their frequency being identified as a frequency region where typical broadband transient excitation does not occur at an amplitude due to partial discharges, with the variance of the filtered signal, which contains at least one time constant of the filter, being subsequently calculated from the filtered signal, such that:

\hat{μ}[k]=λ·\hat{μ}[k−1]+(1−λ)·pd_{filt}[k],

\hat{σ}²[k]=λ·\hat{σ}²[k−1]+(1−λ)·(pd_{filt}[k]−\hat{μ}[k])².

### TECHNICAL FIELD

The invention relates to a method of detecting a partial discharge signal, specifically to a method of detecting a partial discharge signal from a signal measured by a measuring device.

### STATE OF THE ART

The good condition of the insulation of electrical circuits is a basic condition for their proper function. The condition of the insulation is threatened by various factors, such as chemical, electrical or production imperfections. The end state of the insulation is an electric field breakdown and this breakdown is always built up of partial discharges, no matter what impairment of the state of the insulation is created by whichever degradation mechanism, for example degradation of the insulation due to inhomogeneities in production of the insulation, the formation of so-called cavities.

As the electric field approaches, due to polarisation, a positive charge accumulates on one side of the cavity and a negative charge accumulates on the other side. The value of these small charges increases until the moment when the resulting electric potential crosses the insulation barrier and the charges equalise. At that moment, a small discharge is generated, and since the flow of the balancing current stops after the charges have equalised, these discharges are termed partial discharges

Thus, partial discharges in power networks are high-frequency discharges that last in the order of units to tens of nanoseconds and partially bridge the insulation between conductors and appear in the vicinity of the conductors. Partial discharges in transmission networks usually occur in the amplitude of alternating current. Partial discharges generate high-frequency electromagnetic pulses that travel relatively long distances spreading through the power system. Partial discharges are detected in a selected location of the electrical network, usually in nodes such as substations, with the aim being measuring and identifying the partial discharge, its amplitude and phase, and the occurrence of partial discharges from the point of view of other parameters and the frequency of their occurrence to be further analysed with the aim of diagnosing the quality of the line and possible malfunctions.

From patent document U.S. Pat. No. 9,390,067, a partial discharge detection method is known, which uses two sensors installed at the ends of the line. Measurements at both ends must be synchronous in order to perform subsequent localisation of the discharge. Since the signals measured on the lines are disturbed by noises that can completely mask the resulting partial discharges, the Wavelet transform method in combination with statistical processing is used to detect the discharges. Subsequently, the parameters of the discharge are calculated, which are its amplitude, the area of the signal envelope, the phase with respect to the reference voltage, and the position of the partial discharge along the line is determined. The significant disadvantage of this method is the need to use two sensors, which must also be synchronised. Another disadvantage is that the use of the Wavelet Transform described in the patent has been shown in testing to be less robust in regards to higher levels of noise in the signal.

Another method of detection and localisation of partial discharges is known from another patent document U.S. Pat. No. 6,809,523. Discharges are analysed here in the frequency and time domain. This document states that a partial discharge will excite a signal frequency band from 200 kHz to 200 MHz. Depending on which part of the frequency spectrum the dominant amplitude is located, it can be decided whether the discharge occurred closer or further away from the sensor. In the case that the maximum amplitude is at lower frequencies, the discharge occurred at a greater distance than if the maximum amplitude had been at higher frequencies of the spectrum. Subsequently, the phase of the discharge relative to the reference voltage is determined in the time domain and localisation of the discharge is performed.

From patent document US20170336459, a system for the detection and localisation of partial discharges is known, which uses the so-called Phase resolving spectra for the analysis of partial discharges. Also mentioned in this patent is the characteristic of discharges that discharges that occur closer to the sensor have maximum amplitudes at higher frequencies of the spectrum, and discharges that occur at a greater distance that have a maximum value of the spectrum at lower frequencies.

The detection of partial discharges from at least two sensors is known from another patent document U.S. Pat. No. 8,126,664. Measurements at both locations must again be supplemented by synchronisation, which is further used for the localisation of discharges. The diagnostic module of the system uses the characteristics of discharges in the time and time-frequency domain, while the use of the classical short-term Fourier transform, Wavelet transform or Wigner-Ville distribution is assumed. The disadvantage is again the necessity of using two sensors, which greatly complicates not only the construction of the entire measurement system, but also the measurement and evaluation itself.

The main disadvantage of known technology is that most methods require the use of multiple sensors for their implementation, which greatly complicates the measurement.

The aim of the invention is to construct a method of detecting a partial discharge signal from a measured signal, which will bring highly reliable and accurate results, while the equipment which will be required to be used for its operation will be simple and therefore cheap, which will allow its mass use.

### PRINCIPLE OF THE INVENTION

The mentioned shortcomings are largely removed and the objectives of the invention are fulfilled by a method of detecting a partial discharge signal, in particular the method of detecting the partial discharge signal from a measured signal by the measuring device at least one point of the electric network, characterised by that firstly the variables in the detection device are initialised and the parameters Nᵥₐᵣ, lag_max, dead_max are loaded, then the measured broad-spectrum analog signal is loaded at least once, which is converted into a digital signal in the digitising means, which is further band-pass filtered so that components unrelated to the manifestation of partial discharge are removed from it, with their frequency being identified as a frequency region where the typical broadband transient excitation of amplitudes due to partial discharges does not occur, and the variance of the filtered signal is then calculated from the filtered signal, which contains at least one time constant of the filter such that

\hat{μ}[k]=λ·\hat{μ}[k−1]+(1−λ)·pd_{filt}[k],

\hat{σ}²[k]=λ·\hat{σ}²[k−1]+(1−λ)·(pd_{filt}[k]−\hat{μ}[k])²,
where:
   λ is a forgetting factor ranging from 0 to 1, with a typical value of the factor typically ranging from 0.9 to 0.999, where if the variation of the filtered signal exceeds a specified threshold, then the presence of a partial discharge is detected at time k,
   \hat{μ}[k] is an estimate of the mean value of the filtered signal at time k, where the unit is the unit of the filtered signal, i.e. most often the voltage being in volts,
   \hat{μ}[k−1] is an estimate of the mean value of the filtered signal at time k−1, where the unit is the unit of the filtered signal, the voltage being most often in volts,
   pd_{filt}[k] is the value of the filtered signal at time k, where the unit is the unit of the filtered signal, the voltage being most often in volts,
   \hat{σ}²[k] is an estimate of the variance of the filtered signal at time k, where the unit is the square of the unit of the filtered signal, most often the square of the volt, and
   \hat{σ}²[k−1] is an estimate of the variance of the signal at time k−1, where the unit is the square of the unit of the filtered signal, most commonly the square of the volt.

It is to advantage that the signal is first pre-processed with a suitably chosen filter, whereby only a certain frequency band is left depending on the character of the measured signal. Furthermore, it is to advantage that the information about the partial discharge remains in the filtered signal. The variance is calculated from the filtered signal, and the calculation parameter is the forgetting factor. Two variances are used, one to detect the partial discharge and the other to subsequently determine the origin of the partial discharge. It is advantageous to calculate the second variance from the unfiltered signal to accurately determine the origin of the discharge.

It is to advantage when variables are initialised such that:

$$\hat{μ} [ 1 ] = 0 ,$$

$${\hat{σ}}^{2} [ 1 ] = 0 ,$$

$${\hat{μ}}_{2} [ 1 ] = 0 ,$$

$${\hat{σ}}_{2}^{2} [ 1 ] = 0 ,$$

$${\hat{μ}}_{3} [ 1 ] = 0 ,$$

$${\hat{μ}}_{krit} [ 1 ] = 0.$$

The main advantage of this initialisation is the universal setting of the initial values of the variables, without the need to know the current state.

Furthermore, it is advantageous if, in the case of the presence of a partial discharge, the origin of the partial discharge is further determined by first determining the value of the variance \hat{σ}₂² such that:

$${\hat{μ}}_{2} [ k ] = {λ}_{2} \cdot {\hat{μ}}_{2} [ k - 1 ] + ( 1 - {λ}_{2} ) \cdot pd [ k ] ,$$

$${\hat{σ}}_{2}^{2} [ k ] = {λ}_{2} \cdot {\hat{σ}}_{2}^{2} [ k - 1 ] + ( 1 - {λ}_{2} ) \cdot {( pd [ k ] - {\hat{μ}}_{2} [ k ] )}^{2} ,$$

where:
   \hat{μ}₂[k] is an estimate of the mean value of the signal at time k, where the unit is the unit of the measured signal, the voltage being most often in volts,
   λ₂ is the forgetting factor,
   \hat{σ}₂²[k] is an estimate of the variance (dispersion) of the measured signal at time k, where the unit is the square of the unit of the measured signal, i.e. most often the square of the volt,
   \hat{μ}₂ [k−1] is an estimate of the mean value of the signal at time k−1, where the unit is the unit of the measured signal, the voltage being most often in volts,
   \hat{σ}₂²[k−1] is an estimate of the variance of the measured signal at time k−1, where the unit is the square of the unit of the measured signal, i.e. most often the square of the volt, and
   pd[k] is the value of the measured signal at time k, where the unit is the unit of the measured signal, the voltage being most often in volts,
and further, the proportion of variance value \hat{σ}₂² at time k and at time k-Nvar is determined such that:

$$Δ {\hat{σ}}_{2}^{2} [ k ] = \frac{{\hat{σ}}_{2}^{2} [ k ]}{{\hat{σ}}_{2}^{2} [ k - N var ]}$$

where Nvar is a selectable parameter that indicates the number of variance samples (delayed computation) by which the denominator of the above fraction is shifted from the numerator, thus it can take any integer value, with a typical value being 20, and the time of the maximum is stored in memory k_max at a horizon shorter than lag_max, which is typically set to 250, from the current time k, where the start of the burst id_beg is determined such that:

$$id\_beg = k\_max - N var ,$$

while if no new maximum is determined in the following dead_max samples, the moment id_beg is considered the start of the discharge, while if a new maximum Δ\hat{σ}₂² of the function is found in the following dead_max samples, then this new moment id_beg is considered the start of the discharge, with the information about the start being updated in the memory discharges id_beg.

It is also to advantage that for each detected partial discharge, the precise moment of the start of the discharge is determined as the moment of the maximum of the function calculated as the ratio of the variances of two consecutive sliding windows. The advantage is that by applying this procedure, the beginning of the detected partial discharge is the maximum of the above-mentioned proportion, i.e. the maximum of the function Δ\hat{σ}₂².

It is also to advantage if the search for the start of the discharge is terminated after the dead_max of samples from the moment of discharge detection, which is typically set to 50. The advantage of this approach is that the search for the beginning of the partial discharge is limited to a finite number of dead_max samples.

Furthermore, it is to advantage if, in the case of the presence of a partial discharge, the end id_end of the partial discharge is further determined so that the moment at which the value of the criterion function falls below 1.1 times the value of the criterion function at the beginning of the partial discharge it is declared as the end of the partial discharge, such that:

$${\hat{μ}}_{3} [ k ] = {λ}_{3} \cdot {\hat{μ}}_{3} [ k - 1 ] + ( 1 - {λ}_{3} ) \cdot pd [ k ] ,$$

$${\hat{μ}}_{krit} [ k ] = {λ}_{3} \cdot {\hat{μ}}_{krit} [ k - 1 ] + ( 1 - {λ}_{3} ) \cdot \vert pd [ k ] - {\hat{μ}}_{3} [ k ] \vert ,$$

$${\hat{μ}}_{krit} [ id\_end ] < 1 , 1 \cdot {\hat{μ}}_{krit} [ id\_beg ] ,$$

where:
   \hat{μ}₃[k] is an estimate of the mean value of the signal at time k, where the unit is the unit of the measured signal, the voltage being most often in volts,
   λ₃ is the forgetting factor,
   \hat{μ}₃ [k−1] is an estimate of the mean value of the signal at time k, where the unit is the unit of the measured signal, the voltage being most often in volts,
   pd[k] is the value of the measured signal at time k, where the unit is the unit of the measured signal, the voltage being most often in volts,
   \hat{μ}ₖᵣᵢₜ[k] is an estimate of the mean value of the absolute value of the measured signal without the DC component at time k, where the unit is the unit of the measured signal, the voltage being most often in volts, and
   \hat{μ}ₖᵣᵢₜ[k−1] is an estimate of the mean value of the absolute value of the measured signal without the DC component at time k−1, where the unit is the unit of the measured signal, the voltage being most often in volts.

It is to advantage that the end of the partial discharge is calculated from the recursively calculated sum of the absolute value of the signal and its value at the beginning and end of the partial discharge is compared. Another advantage of this procedure is the speed and simplicity of implementing this procedure in the measuring and evaluation device.

It is also to advantage if, in the presence of a partial discharge, the total charge Q is further determined such that:

$$Q = a \cdot \frac{1}{{f}_{s}} {\sum }_{i = id \_ beg}^{id \_ end} \vert pd [ i ] \vert$$

where:
   Q is the total charge determined, where the unit is the Coulomb,
a is the calibration coefficient of the conversion of signal area to charge, with the unit being

$$\frac{A \cdot s}{V} ) ,$$

fₛ is the sampling frequency, where the unit is Hz, and
i is the sum calculation index from sample id_beg to sample id_end.

The advantage of determining the total charge Q is the possibility to determine the size of the discharge and thus categorise the partial discharge according to its size.

It to advantage when, in the presence of a partial discharge, the phase in the basic harmonic sinusoid of the voltage in the electricity network is further determined such that:

$$φ = ( {id}_{beg} / {f}_{s} - {t}_{0} ) \frac{360}{T} ,$$

where:
   φ is the initial phase of the network voltage at the moment of partial discharge, where the unit is degree,
   t₀ is the absolute start time of the current voltage period,
   id_beg the beginning of the discharge is identified,
   fₛ is the sampling frequency, where the unit is Hz, and
   T is the duration of the last full period in seconds,
with the duration T of the last full period being used as the AC voltage period and t₀ being the start time of the current voltage period.

The main advantage of the partial discharge signal detection method, according to the invention, is that the proposed method allows detecting a greater number of discharges (or nearly all) than the compared methods, which is very significant from the point of view of determining the degradation of the insulation properties of the line. Thanks to this, it is possible to simply and cheaply determine the insulation status of the object being measured. This method of online detection of partial discharges in electrical networks is based on advanced signal processing, most often measured by a measuring transformer at at least one location of the electrical system. Determining the moments in time when the sliding variance estimate exceeds the selected threshold means the detection of partial discharges. Subsequently, the process of loading the new value of the measured signal, calculating the filtered value of the signal, recursively calculating two sliding variances with different time constants, recursively calculating the moving sum used in determining the end of the discharge and finally calculating the parameters of partial discharges in the case of its detection is repeated repeatedly. The selectability of filter coefficients enables especially switching between PP and DP filters, as well as suitable settings of the filter parameters. The detection method uses a set of predefined filters, from which the one that will suppress unwanted noise the most while preserving the manifestations of the partial discharges being sought is selected for the given installation. The method of detection of the partial discharge signal, according to the invention, is directly focused on the detection of non-stationarities in the measured signal, i.e. “burst” type changes, to which it is very sensitive. Compared to the commonly used DWT method, the resulting detection is not disturbed by falsely identified partial discharges.

### OVERVIEW OF THE FIGURES

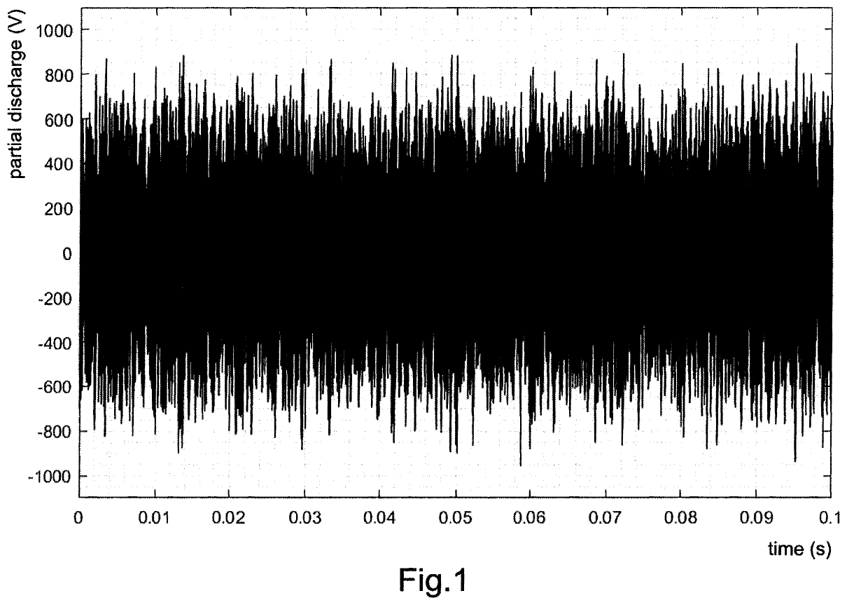

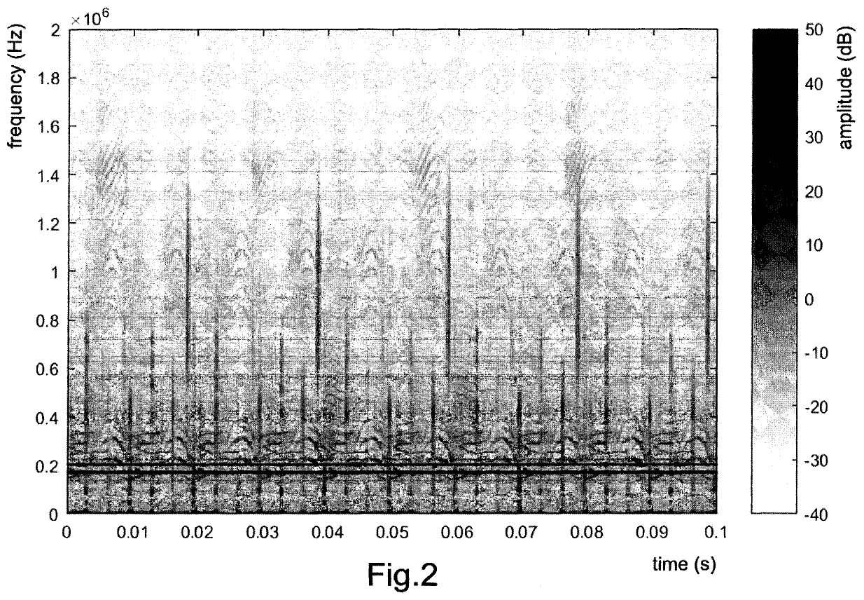

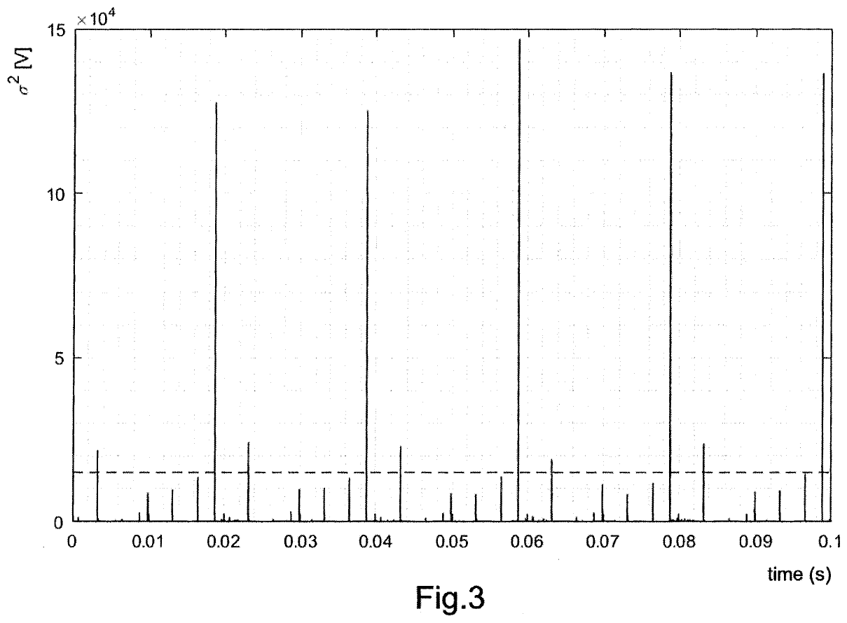

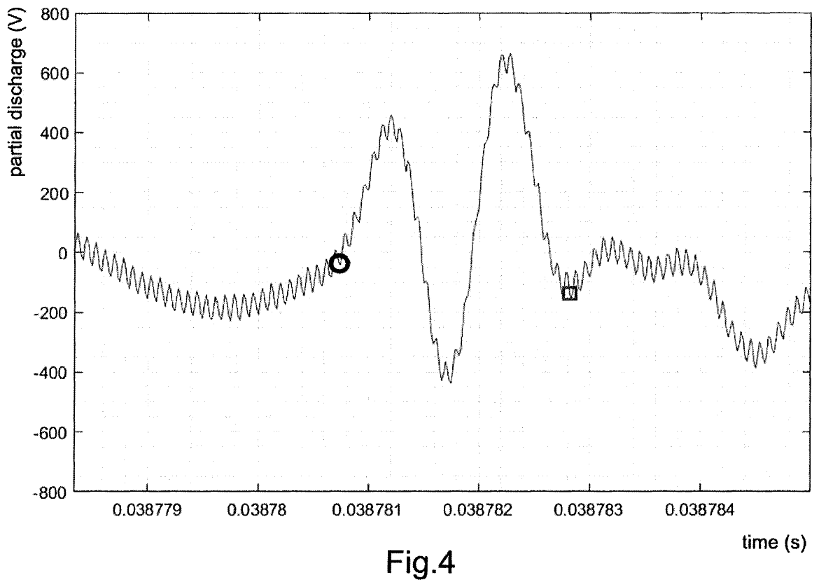

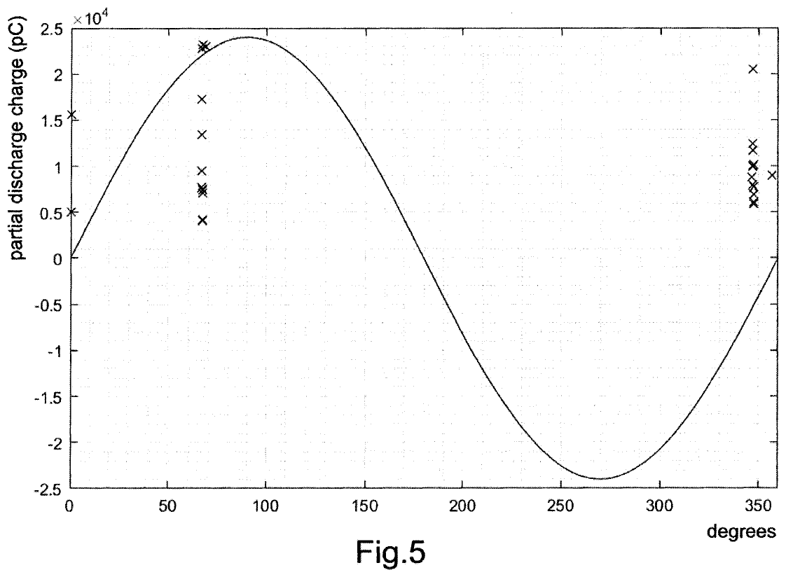

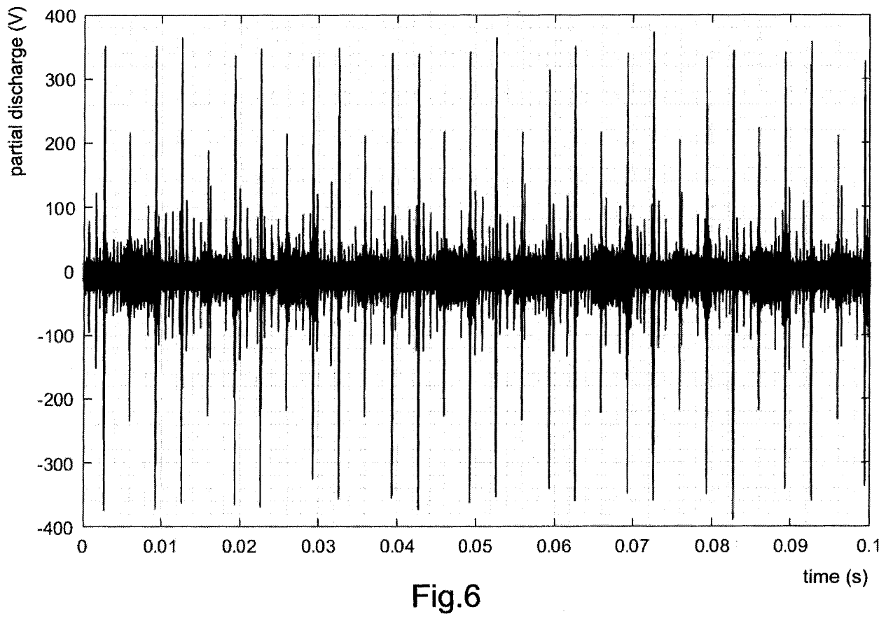

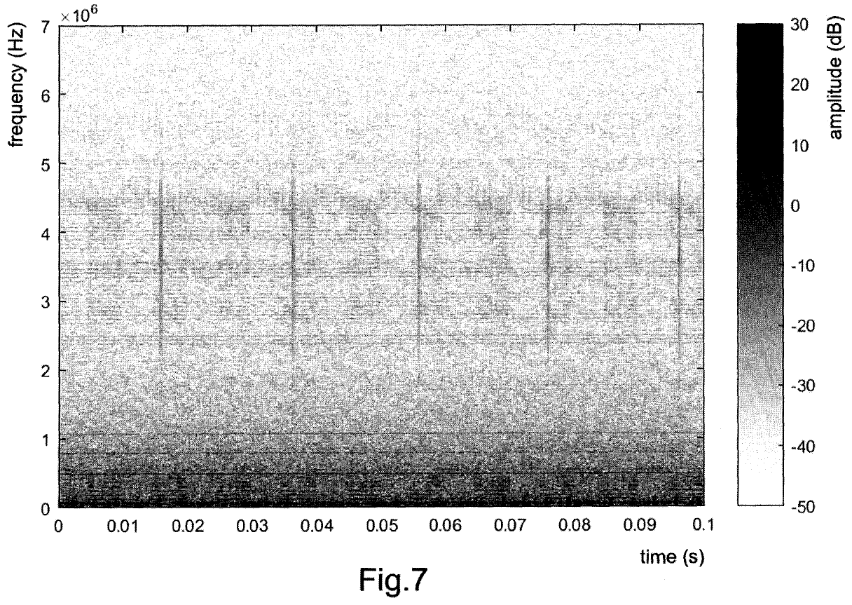

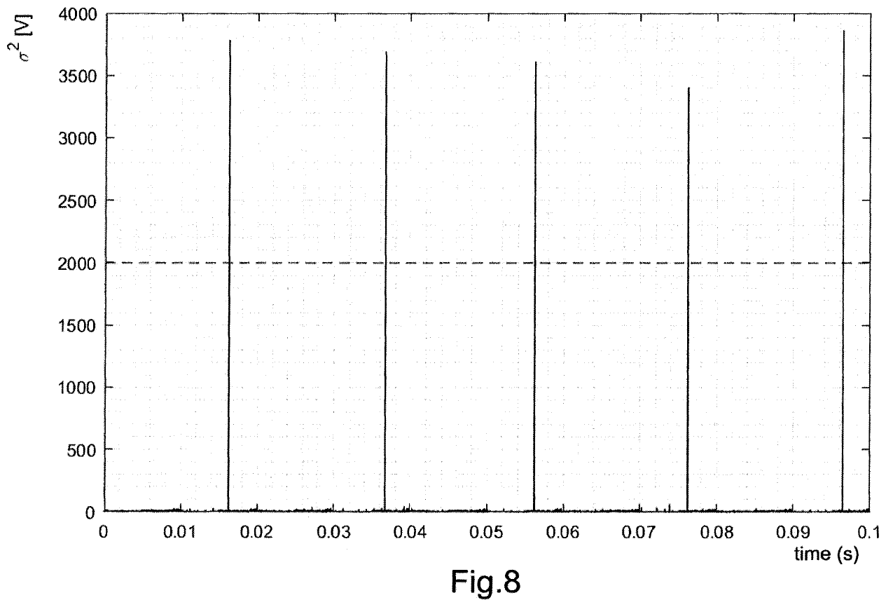

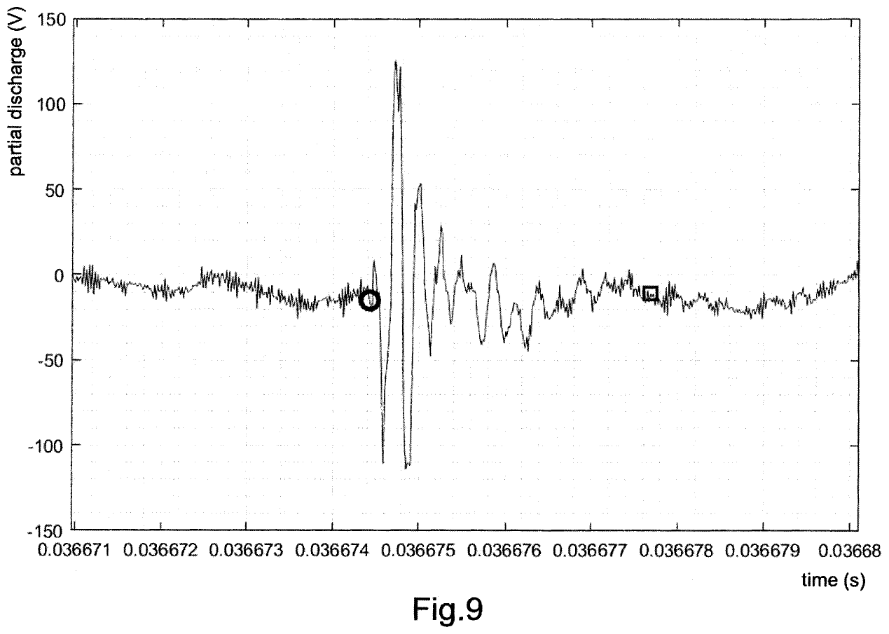

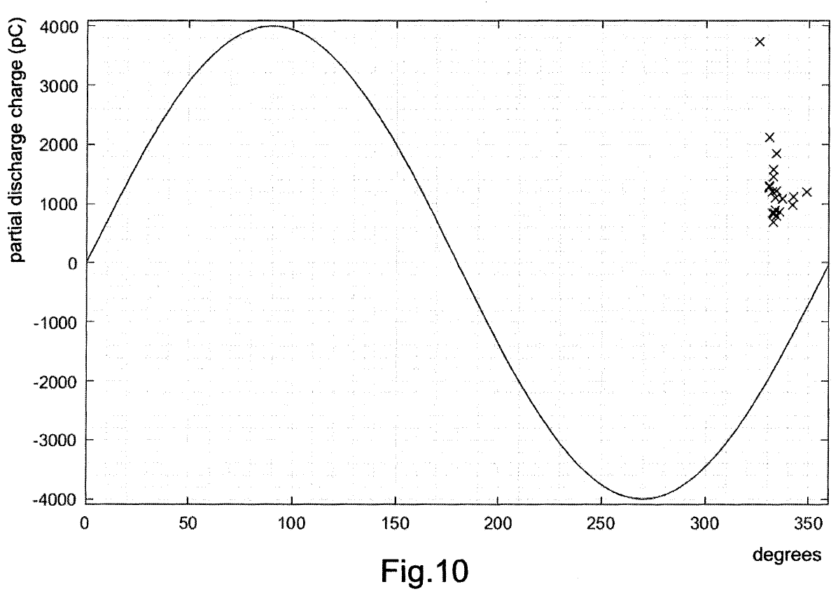

The invention will be explained in more detail with the help of the drawing, in which FIG. 1 shows the graphic course of the partial discharge time course according to the first example of the design, FIG. 2 shows the amplitude spectrogram of the partial discharge signal according to the first example of the design, FIG. 3 shows the time course of the signal variance including the marked detection threshold of partial discharges according to the first example of the design, FIG. 4 shows the time evolution of the partial discharge signal together with marking the beginning (circle) and end (square) of the partial discharge according to the first example of the design, FIG. 5 shows the PDPR (Partial Discharge Phase Resolved) diagram according to the first example of the design, FIG. 6 shows graphically the time course of a partial discharge according to the second example of the design, FIG. 7 shows the amplitude spectrogram of the partial discharge signal according to the second example of the design, FIG. 8 shows the time course of the variance of the signal including the indicated threshold for the detection of partial discharges according to the second example of the design, FIG. 9 shows the time evolution of the partial discharge signal along with marking the beginning (circle) and end (square) of the partial discharge according to the second example of the design, and FIG. 10 shows the PDPR diagram according to the second example of the design.

### EXAMPLES OF THE PERFORMANCE OF THE INVENTION

### Example 1

The method of detecting the partial discharge signal from the measured signal is performed by a measuring device arranged at one point of the electrical network.

Firstly, variables are initialised in the detection device, which is a computer, and the parameters Nᵥₐᵣ=20, lag_max=250, dead_max=50 are loaded, then the measured wide-spectrum analog signal is loaded at least once, which is converted into a digital signal in the digitising device (FIG. 1), which is further band-pass filtered with a band-pass filter with a range from 400 kHz to 1.5 MHz so that components unrelated to the manifestation of partial discharge are removed from it, where their frequency is identified as a frequency range from 0 to 400 KHz and frequencies higher than 1.5 MHz, where there is no typical broadband transient excitation of amplitudes due to partial discharges (FIG. 2), while the variance of the filtered signal is subsequently calculated from the filtered signal (FIG. 3), which contains exactly one forgetting factor such that

$$\hat{μ} [ k ] = λ \cdot \hat{μ} [ k - 1 ] + ( 1 - λ ) \cdot {pd}_{filt} [ k ] ,$$

$${\hat{σ}}^{2} [ k ] = λ \cdot {\hat{σ}}^{2} [ k - 1 ] + ( 1 - λ ) \cdot {( {pd}_{filt} [ k ] - \hat{μ} [ k ] )}^{2} ,$$

where:
   λ=0.9667 forgetting factor, while if the variance of the filtered signal exceeds the set threshold of 15000, the presence of a partial discharge is detected at time k,
   \hat{μ}[k] is an estimate of the mean value of the filtered signal at time k (V),
   \hat{μ}[k−1] is an estimate of the mean value of the filtered signal at time k−1 (V),
   pd_{filt}[k] is the value of the filtered signal at time k (V),
   \hat{σ}²[k] is an estimate of the variance (dispersion) of the filtered signal at time k in volts squared (V²), and
   \hat{σ}²[k−1] is an estimate of the variance (dispersion) of the signal at time k−1 in volts squared (V²).
      Next, the variables are initialised so that:

$$\hat{μ} [ 1 ] = 0 ,$$

$${\hat{σ}}^{2} [ 1 ] = 0 ,$$

$${\hat{μ}}_{2} [ 1 ] = 0 ,$$

$${\hat{σ}}_{2}^{2} [ 1 ] = 0 ,$$

$${\hat{μ}}_{3} [ 1 ] = 0 ,$$

$${\hat{μ}}_{krit} [ 1 ] = 0.$$

Furthermore, in the case of the presence of a partial discharge, the beginning of the partial discharge is determined by first determining the value of the variance \hat{σ}₂² such that:

$${\hat{μ}}_{2} [ k ] = {λ}_{2} \cdot {\hat{μ}}_{2} [ k - 1 ] + ( 1 - {λ}_{2} ) \cdot pd [ k ] ,$$

$${\hat{σ}}_{2}^{2} [ k ] = {λ}_{2} \cdot {\hat{σ}}_{2}^{2} [ k - 1 ] + ( 1 - {λ}_{2} ) \cdot {( pd [ k ] - {\hat{μ}}_{2} [ k ] )}^{2} ,$$

where:
   \hat{μ}₂[k] is an estimate of the mean value of the signal at time k (V),
   λ₂=0.9167 is the forgetting factor,
   \hat{σ}₂²[k] is an estimation of the variance (dispersion) of the measured signal at time k in the square of the volt (V²),
   \hat{μ}²[k−1] is an estimate of the mean value of the signal at time k−1 (V),
   \hat{σ}²[k−1] is an estimation of the variance (dispersion) of the measured signal at time k−1 in volts squared (V²), and
   pd[k] is the value of the measured signal at time k (V),
and further, the proportion of the variance value of \hat{σ}₂² at time k and at time k-Nvar is determined such that:

$$Δ {\hat{σ}}_{2}^{2} [ k ] = \frac{{\hat{σ}}_{2}^{2} [ k ]}{{\hat{σ}}_{2}^{2} [ k - Nvar ]}$$

where Nvar=20 is a parameter that indicates the number of variance samples (calculation delay) by which the denominator of the above-mentioned fraction is shifted compared to the numerator, and the maximum time k_max is stored in the memory in a horizon shorter than lag_max=250 (number of time samples of the signal) from the current time k, with the start of the discharge id_beg determined such that:

$$id\_beg = k\_max - Nvar ,$$

whereas if no new maximum is determined in the following dead_max=50 samples, the moment id_beg is considered to be the start of the discharge, while if a new maximum of the function is found in the following dead_max samples Δ\hat{σ}₂² then this new moment id_beg is considered to be the start of the discharge, with the start of discharge id_beg being updated in memory.

After the expiration of dead_max=50 (number of signal time samples) samples from the moment of discharge detection, the search for the beginning of the discharge is finished.

In the case of the presence of a partial discharge, the end id_end of the partial discharge is further determined so that the moment (FIG. 4) at which the value of the criterion function falls below 1.1 times the value of the criterion function at the beginning of the partial discharge it is declared to be the end of the partial discharge, such that:

$${\hat{μ}}_{3} [ k ] = {λ}_{3} \cdot {\hat{μ}}_{3} [ k - 1 ] + ( 1 - {λ}_{3} ) \cdot pd [ k ] ,$$

$${\hat{μ}}_{krit} [ k ] = {λ}_{3} \cdot {\hat{μ}}_{krit} [ k - 1 ] + ( 1 - {λ}_{3} ) \cdot \vert pd [ k ] - {\hat{μ}}_{3} [ k ] \vert ,$$

$${\hat{μ}}_{krit} [ id\_end ] < 1 , 1 \cdot {\hat{μ}}_{krit} [ id\_beg ] ,$$

where:
   \hat{μ}₃[k] is an estimate of the mean value of the signal at time k (V),
   λ₃=0.9444 is the forgetting factor,
   \hat{μ}₃[k−1] is an estimate of the mean value of the signal at time k−1 (V),
   pd[k] is the value of the measured signal at time k (V),
   \hat{μ}ₖᵣᵢₜ[k] is an estimate of the mean value of the absolute value of the measured signal without the DC component at time k (V), and
   \hat{μ}ₖᵣᵢₜ[k−1] is an estimate of the mean value of the absolute value of the measured signal without the DC component at time k−1 (V).

In the presence of a partial discharge, the total charge Q is further determined such that:

$$Q = a \cdot \frac{1}{{f}_{s}} {\sum }_{i = id \_ beg}^{id \_ end} \vert pd [ i ] \vert$$

where:
   Q is the total determined charge (C),
   a=4900 is the calibration coefficient of conversion of signal area to charge, which has a unit

$$\frac{A \cdot s}{V} ,$$

fₛ=is the 60 MHz sampling frequency, and
i is the sum calculation index from sample id_beg to sample id_end.

In the case of the presence of a partial discharge, the phase in the basic harmonic sinusoid of the voltage in the electricity network (FIG. 5) is further determined such that:

$$φ = ( {id}_{beg} / {f}_{s} - {t}_{0} ) \frac{360}{T} ,$$

where:
   φ is the initial phase of the network voltage at the moment of partial discharge (°),
   t₀ is the absolute start time of the current voltage period (s),
   id_beg is the start of the discharge identified,
   fₛ is the sampling frequency (Hz), and
   T is the duration of the last full period (s),
   where the duration of the last full period T is used as the AC voltage period and t₀ is the start time of the current voltage period.

### Example 2

The method of detecting the partial discharge signal from the measured signal is performed by a measuring device arranged at one point of the electrical network.

Firstly, variables are initialised in the detection device, which is a special device for detection, and the parameters Nᵥₐᵣ=20, lag_max=250, dead_max=50 are loaded, then the measured wide-spectrum analog signal is loaded at least once, which is converted into a digital signal in the digitiser (FIG. 6), which is further band-pass filtered with a band-pass filter with a range from 2 MHz to 5 MHZ, so that the components that are not related to the manifestation of a partial discharge are removed from it, where their frequency is identified as a frequency range from 0 to 2 MHz and a frequency higher than 5 MHz, where there is no typical broadband transient excitation of amplitudes due to partial discharges (FIG. 7), with the variance of the filtered signal being subsequently calculated from the filtered signal (FIG. 8), which contains at least one time constant of the filter such that

$$\hat{μ} [ k ] = λ \cdot \hat{μ} [ k - 1 ] + ( 1 - λ ) \cdot {pd}_{filt} [ k ] ,$$

$${\hat{σ}}^{2} [ k ] = λ \cdot {\hat{σ}}^{2} [ k - 1 ] + ( 1 - λ ) \cdot {( {pd}_{filt} [ k ] - \hat{μ} [ k ] )}^{2} ,$$

where:
   λ=0.9667 is the forgetting factor, while if the variance of the filtered signal exceeds the set threshold of 2000, the presence of a partial discharge is detected at time k,
   \hat{μ}[k] is an estimate of the mean value of the filtered signal at time k (V),
   \hat{μ}[k−1] is an estimate of the mean value of the filtered signal at time k−1 (V),
   pd_{filt}[k] is the value of the filtered signal at time k (V),
   \hat{σ}²[k] is an estimate of the variance (dispersion) of the filtered signal at time k in volts squared (V²), and
   \hat{σ}²[k−1] is an estimate of the variance (dispersion) of the signal at time k−1 in volts squared (V²).
      Next, the variables are initialised such that:

$$\hat{μ} [ 1 ] = 0 ,$$

$${\hat{σ}}^{2} [ 1 ] = 0 ,$$

$${\hat{μ}}_{2} [ 1 ] = 0 ,$$

$${\hat{σ}}_{2}^{2} [ 1 ] = 0 ,$$

$${\hat{μ}}_{3} [ 1 ] = 0 ,$$

$${\hat{μ}}_{krit} [ 1 ] = 0.$$

In the case of the presence of a partial discharge, the beginning of the partial discharge is determined by first determining the value of the variance \hat{σ}₂² such that:

$${\hat{μ}}_{2} [ k ] = {λ}_{2} \cdot {\hat{μ}}_{2} [ k - 1 ] + ( 1 - {λ}_{2} ) \cdot pd [ k ] ,$$

$${\hat{σ}}_{2}^{2} [ k ] = {λ}_{2} \cdot {\hat{σ}}_{2}^{2} [ k - 1 ] + ( 1 - {λ}_{2} ) \cdot {( pd [ k ] - {\hat{μ}}_{2} [ k ] )}^{2} ,$$

where:
   \hat{μ}₂[k] is an estimate of the mean value of the signal at time k (V),
   λ₂=0.9167 is the forgetting factor,
   \hat{σ}₂²[k] is an estimate of the variance (dispersion) of the filtered signal at time k in volts squared (V²), and
   \hat{μ}₂[k−1] is an estimate of the mean value of the signal at time k−1 (V),
   \hat{σ}₂²[k−1] is an estimate of the variance (dispersion) of the filtered signal at time k in volts squared (V²), and
   pd[k] is the value of the measured signal at time k in volts,
and further, the proportion of the variance value of \hat{σ}₂² at time k and at time k-Nvar is determined such that:

$$\\ Δ \hat{σ} {}_{2}^{{}_{} 2} [ k ] = \frac{\hat{σ} {}_{2}^{{}_{} 2} [ k ]}{\hat{σ} {}_{2}^{{}_{} 2} [ k - N var ]}$$

where Nvar=20 is a parameter that indicates the number of variance samples (delayed calculation) by which the denominator of the above fraction is shifted compared to the numerator, and the maximum time k_max being further stored in the memory in a horizon shorter than lag_max=250 (the number of signal time samples) from the current time k, with the start of the discharge id_beg determined such that:

$$\\ id\_beg = k\_max - N var ,$$

whereas if no new maximum is determined in the following dead_max=50 samples, the moment id_beg is considered the start of the discharge, while if a new maximum of the function Δ\hat{σ}₂² is found in the following dead_max samples, then this new moment id_beg is considered to be the start of the discharge, with the data being updated in the memory about the beginning of the discharge id_beg.

After the expiration of dead_max=50 (number of signal time samples) samples from the moment of discharge detection, the search for the beginning of the discharge is completed.

In the case of the presence of a partial discharge, the end id_end of the partial discharge is further determined so that the moment (FIG. 9) at which the value of the criterion function falls below 1.1 times the value of the criterion function at the beginning of the partial discharge is declared to be the end of the partial discharge, such that:

$$\\ {\hat{μ}}_{3} [ k ] = {λ}_{3} \cdot {\hat{μ}}_{3} [ k - 1 ] + ( 1 - {λ}_{3} ) \cdot pd [ k ] ,$$

$$\\ {\hat{μ}}_{krit} [ k ] = {λ}_{3} \cdot {\hat{μ}}_{krit} [ k - 1 ] + ( 1 - {λ}_{3} ) \cdot \vert pd [ k ] - {\hat{μ}}_{3} [ k ] \vert ,$$

$$\\ {\hat{μ}}_{krit} [ id\_end ] < 1 , 1 \cdot {\hat{μ}}_{krit} [ id\_beg ] ,$$

where:
   \hat{μ}₃[k] is an estimate of the mean value of the signal at time k (V),
   λ₃=0.9444 is the forgetting factor,
   \hat{μ}₃[k−1] is an estimate of the mean value of the signal at time k−1 (V),
   pd[k] is the value of the measured signal at time k (V),
   \hat{μ}ₖᵣᵢₜ[k] is an estimate of the mean value of the absolute value of the measured signal without the DC component at time k (V),
   \hat{μ}ₖᵣᵢₜ[k−1] is an estimate of the mean value of the absolute value of the measured signal without the DC component at time k−1 (V).

In the case of the presence of a partial discharge, the total charge Q is further determined such that:

$$\\ Q = a \cdot \frac{1}{{f}_{s}} {\sum }_{i = id \_ beg}^{id \_ end} \vert pd [ i ] \vert$$

where:
   Q is the total determined charge (C),
   a=4500 is the calibration coefficient of conversion of signal area to charge, which has a unit

$$\\ \frac{A \cdot s}{V} ,$$

fₛ=60 MHz is the sampling frequency, and
i is the sum calculation index from sample id_beg to sample id_end.

In the case of the presence of a partial discharge, the phase in the basic harmonic sinusoid of the voltage in the electricity network (FIG. 10) is further determined such that:

$$\\ φ = ( {id}_{beg} / {f}_{s} - {t}_{0} ) \frac{360}{T} ,$$

where:
   φ is the initial phase of the voltage in the network at the moment of the occurrence of partial discharge (°),
   t₀ is the absolute start time of the current voltage period (s),
   id_beg is the start of the discharge identified,
   fₛ is the sampling frequency (Hz), and
   T is the duration of the last full period (s),
   with the duration of the last full period T being used as the AC voltage period and t₀ being the start time of the current voltage period.

### INDUSTRIAL APPLICATION

The method of detecting a partial discharge signal, can specifically be used to detect the partial discharge signal in common industrial applications, especially on power lines.

1. A method of detecting a partial discharge signal, in particular a method of detecting a partial discharge signal from a signal measured by a measuring device at at least one point of the electrical network, comprising:
first initializing the variables in the detection device,
loading the parameters Nᵥₐᵣ, lag_max, dead_max,
loading the measured broad-spectrum analog signal at least once, which is converted into a digital signal in a digitising means, which is further band-pass filtered so that components unrelated to a manifestation of partial discharge are removed from it, where their frequency is identified as a frequency region where a broadband transient excitation of amplitudes due to partial discharges does not occur, and
calculating the variance of the filtered signal from the filtered signal, which contains at least one time constant of the filter such that,
$$\\ \hat{μ} [ k ] = λ \cdot \hat{μ} [ k - 1 ] + ( 1 - λ ) \cdot {pd}_{filt} [ k ] ,$$
$$\\ \hat{σ} {}^{{}_{} 2} [ k ] = λ \cdot \hat{σ} {}^{{}_{} 2} [ k - 1 ] + ( 1 - λ ) \cdot {( {pd}_{filt} [ k ] - \hat{μ} [ k ] )}^{2} ,$$
where:
λ is a forgetting factor in a range 0 to 1, whereby if a variance of the filtered signal exceeds a specified threshold, the presence of a partial discharge is detected at time k,
\hat{μ}[k] is an estimate of a mean value of the filtered signal at time k (V),
\hat{μ}[k−1] is an estimate of a mean value of the filtered signal at time k−1,
pd_{filt}[k] is a value of the filtered signal at time k,
\hat{σ}²[k] is an estimate of a variance of the filtered signal at time k, and
\hat{σ}²[k−1] is an estimate of a variance of the signal at time k−1.

2. The method of detecting a partial discharge signal, according to claim 1, wherein the variables are initialised such that:
$$\\ \hat{μ} [ 1 ] = 0 , \hat{σ} {}^{{}_{} 2} [ 1 ] = 0 , {\hat{μ}}_{2} [ 1 ] = 0 , \hat{σ} {}_{2}^{{}_{} 2} [ 1 ] = 0 , {\hat{μ}}_{3} [ 1 ] = 0 , {\hat{μ}}_{krit} [ 1 ] = 0.$$

3. The method of detecting a partial discharge signal, according to claim 1, wherein that in the case of the presence of a partial discharge, the beginning of the partial discharge is further determined by first determining the value of the variance \hat{σ}₂² so that:
$$\\ {\hat{μ}}_{2} [ k ] = {λ}_{2} \cdot {\hat{μ}}_{2} [ k - 1 ] + ( 1 - {λ}_{2} ) \cdot pd [ k ] ,$$
$$\\ \hat{σ} {}_{2}^{{}_{} 2} [ k ] = {λ}_{2} \cdot \hat{σ} {}_{2}^{{}_{} 2} [ k - 1 ] + ( 1 - {λ}_{2} ) \cdot {( pd [ k ] - {\hat{μ}}_{2} [ k ] )}^{2} ,$$
where:
\hat{μ}₂[k] is an estimate of the mean value of the signal at time k,
λ₂ is the forgetting factor,
\hat{σ}₂²[k] is an estimate of the variance (dispersion) of the measured signal at time k,
\hat{μ}₂[k−1] is an estimate of the mean value of the signal at time k−1,
\hat{σ}₂²[k−1] is an estimate of the variance of the measured signal at time k−1, and
pd[k] is the value of the measured signal at time k,
and further, the proportion of the variance value of \hat{σ}₂² at time k and at time k-Nvar is determined such that:
$$\\ Δ \hat{σ} {}_{2}^{{}_{} 2} [ k ] = \frac{\hat{σ} {}_{2}^{{}_{} 2} [ k ]}{\hat{σ} {}_{2}^{{}_{} 2} [ k - N var ]}$$
where Nvar is an selectable parameter that indicates the number of variance samples by which the denominator of the above fraction is shifted from the numerator, and the time of the maximum k_max is stored in memory in a horizon shorter than lag_max from the current time k, and the start of the discharge id_beg is determined such that:
$$\\ id\_beg = k\_max - N var ,$$
whereas if no new maximum is determined in the following dead_max samples, the moment id_beg is considered the start of the discharge, and if a new maximum of the function Δ\hat{σ}₂² is found in the following dead_max samples, then this new moment id_beg is considered to be the start of the discharge, and the information about start of discharge id_beg is updated in the memory.

4. The method of detecting a partial discharge signal, according to claim 2, wherein after the dead_max of samples have elapsed from the moment of discharge detection, the search for the start of the discharge is terminated.

5. The method of detecting a partial discharge signal, according to claim 1, wherein in the case of the presence of a partial discharge, the end id_end of the partial discharge is further determined so that the moment at which the value of the criterion function falls below 1.1 times the value of the criterion function at the beginning of the partial discharge it is declared as the end of the partial discharge, such that:
$$\\ {\hat{μ}}_{3} [ k ] = {λ}_{3} \cdot {\hat{μ}}_{3} [ k - 1 ] + ( 1 - {λ}_{3} ) \cdot pd [ k ] ,$$
$$\\ {\hat{μ}}_{krit} [ k ] = {λ}_{3} \cdot {\hat{μ}}_{krit} [ k - 1 ] + ( 1 - {λ}_{3} ) \cdot \vert pd [ k ] - {\hat{μ}}_{3} [ k ] \vert ,$$
$$\\ {\hat{μ}}_{krit} [ id\_end ] < 1 , 1 \cdot {\hat{μ}}_{krit} [ id\_beg ] ,$$
where:
\hat{μ}₃[k] is an estimate of the mean value of the signal at time k,
λ₃ is the forgetting factor,
\hat{μ}₃ [k−1] is an estimate of the mean value of the signal at time k−1,
pd[k] is the value of the measured signal at time k,
\hat{μ}ₖᵣᵢₜ[k] is an estimate of the mean value of the absolute value of the measured signal without the DC component at time k, and
\hat{μ}ₖᵣᵢₜ[k−1] is an estimate of the mean absolute value of the measured signal without the DC component at time k−1.

6. The method of detecting a partial discharge signal, according to claim 1, wherein in the case of the presence of a partial discharge, the total charge Q is further determined such that:
$$\\ Q = a \cdot \frac{1}{{f}_{s}} {\sum }_{i = id \_ beg}^{id \_ end} \vert pd [ i ] \vert$$
where:
Q is the total determined charge,
a is the calibration coefficient of the conversion of signal area to charge,
fₛ is the sampling frequency, and
i is the sum calculation index from sample id_beg to sample id_end.

7. The method of detecting a partial discharge signal, according to claim 1, wherein in the case of the presence of a partial discharge, the phase in the basic harmonic sinusoid of the voltage in the electrical network is further determined such that:
$$\\ φ = ( {id}_{beg} / {f}_{s} - {t}_{0} ) \frac{360}{T} ,$$
where:
φ is the initial phase of the voltage in the network at the moment of partial discharge,
t₀ is the absolute start time of the current voltage period,
id_beg is the start of the discharge identified,
fₛ is the sampling frequency (Hz), and
T is the duration of the last full period (s),
where the duration of the last full period T is used as the AC voltage period and t₀ is the start time of the current voltage period.
